(19) United States
(12) Patent Application Publication
(10) Pub. No.: US 2002/0014701 A1
(43) Pub. Date: Feb. 7, 2002

(54) Interconnect structure for semiconductor device and method of fabrication

(75) Inventors: Won-Cheol Cho, Seoul (KR); Wouns Yang, Cheongju-shi (KR)

Correspondence Address: BIRCH STEWART KOLASCH & BIRCH, PO BOX 747, FALLS CHURCH, VA, 22040-0747, US

(73) Assignee: Hyundai Electronics Industries Co., Ltd.

(21) Appl. No.: 09/953,152

(22) Filed: Sep. 17, 2001

Related U.S. Application Data
(63) Continuation of application No. 09/568,038, filed on May 10, 2000.

(30) Foreign Application Priority Data
May 10, 1999 (KR) 99-16576

(51) Int. Cl. H01L 23/48

(52) U.S. Cl. 257/774; 257/750

(57) ABSTRACT

The interconnect structure for semiconductor devices includes a semiconductor substrate, an insulating layer on the semiconductor substrate, a first back-up layer on the insulating layer, a first conductive layer on the first back-up layer, a second back-up layer on the first conductive layer, a second conductive layer on the second back-up layer, and a third back-up layer on the second conductive layer. The first and second conductive layers are formed of aluminum-based alloys, and the first to third back-up layers are formed of aless conductive material such as transition metal alloys.

### BACKGROUND OF THE INVENTION

1. Field of Invention

The present invention relates in general to an interconnect structure for semiconductor devices which prevents electromigration damage and a method of fabricating such a structure.

2. Discussion of Related Art

Patterned aluminum thin films have been the most widely used interconnect structures in the manufacture of silicon integrated circuits (ICs). The main reasons for the pervasiveness of Al are its low resistivity (2.7 μω-cm) and its good adhesion to a silicon oxide layer and a silicon layer. Yet, low melting temperature (660° C.) and eutectic temperature (577° C.) are the main limitations of Al. Hillocks formed at relatively low processing temperatures (i.e. above 300° C.) offer relatively poor resistance to electromigration (hereinafter abbreviated EM) effects. EM is the motion of the ions of a conductor such as Al in response to the passage of current through it wherein the ions are moved downstream by the force of the electron wind. A positive divergence of the ionic flux leads to an accumulation of vacancies, forming a void in the metal. Such voids may ultimately grow to a size that results in an open-circuit failure of the conductor line. Hence, electromigration is a wearout mechanism.

In general, the electromigration failure rate is increased when the current density in the conductor line is increased or the operating temperature is raised. Thinning of the conductor lines as they cross steep steps will also accelerate electromigration failure rates, because the current density at such locations along a line are increased. Various structures and processes are proposed to improve EM damage resistance. One of them is the triple layer sandwich Al structure, with a highly electromigration-resistant metal as the bottom and top layers of the triple layer structure.

FIGS. 1A to 1B show the cross-sectional views of an interconnect in a semiconductor device according to a related art.

Referring to FIG. 1A, a thick insulating layer 15 is formed on a semiconductor substrate 11 by deposition. A first back-up layer 17, a conductive layer 19 and a second back-up layer 21 are formed on the insulating layer 15 successively by deposition. Then, an interconnect 39 having a triple-layered structure is formed by patterning the first back-up, conductive and second back-up layers 17, 19 and 21 by a photo-etch method. A passivation layer (not shown in the drawing) is then formed on the interconnect 39.

The insulating layer 15 is formed by depositing silicon oxide through chemical vapor deposition (hereinafter abbreviated CVD). The first and second back-up layers 17 and 21 are formed by depositing one of Ti, W, Mo, another transition metal or an alloy thereof by sputtering. The conductive layer 19 is formed with Al by sputtering using 0.5 to 1.5 wt % silicon, 0.5 to 1.5 wt % Cu and/or another metal alloy as the target material. Therefore, an interconnect of the sandwich structure is achieved wherein the upper and lower layers, with respect to the conductive layer 19, are the back-up layers.

Referring to FIG. 1B, once electrical current of high density is applied to the interconnect 39, metal atoms of Al migrate from regions of the conductive layer 19 to other regions. Then, voids 40a and 40b are generated locally in the conductive layer 19 by the movement of the metal atoms. The Al conductive layer 19 in the interconnect 39 becomes open due to the voids 40a and 40b.

Stress migration is caused by thermal stresses produced by the mismatch between the coefficients of thermal expansion of the metal interconnect 39 and its surrounding insulating layer 15 and passivation layers(not shown in the drawing). Depending on prior thermal history, the thermal stresses can either be tensile or compressive leading to void formation or hillock growth, respectively.

Thermal-stress-induced voids participate in the electromigration damage processes in various ways depending on their sizes. When the sizes of these voids are large, they migrate under electrical currents without being trapped by barriers such as grain boundaries. When the sizes of theses voids are small, they are first trapped at grain and other boundaries and grow through electrical-current-induced atomic transport until they are sufficiently large to free themselves from the barriers and migrate. Migrating voids coalesce with other voids and thus provide an effective means for void growth. Independently of the mechanism of void growth, continued void growth will eventually sever an interconnect.

When thermal-stress-induced voids are absent in a metal interconnect, the electrical-current-induced atomic transport discussed above will produce high tensile stresses at locations where excess vacancies are accumulated. Such high tensile stresses are believed to cause the nucleation of voids that participate in EM damage processes in the same way as small and trapped thermal-stress-induced voids.

The back-up layers provide electrical continuity when the Al-based layer fails because of stress migration and/or EM damage. The high melting temperatures of refractory metals or metal alloys are the reason for their immunity to stress migration and EM damage. However, their high resistances prevent their use for the primary conducting layer as well.

### SUMMARY OF THE INVENTION

Accordingly, the present invention is directed to an interconnect structure for semiconductor devices and a method of fabricating an interconnect structure for semiconductor devices that substantially obviate one or more of the problems due to limitations and disadvantages of the related art.

The object of the present invention is to provide an interconnect structure for semiconductor devices and a method for fabricating such a structure which eliminates or substantially reduces EM damage.

Additional features and advantages of the invention will be set forth in the description which follows and in part will be apparent from the description, or may be learned by practice of the invention. The objectives and other advantages of the invention will be realized and attained by the structure particularly pointed out in the written description and claims hereof as well as the appended drawings.

To achieve these and other advantages and, in accordance with the purpose of the present invention, as embodied and broadly described, the present invention includes a semiconductor substrate, an insulating layer formed over the semiconductor substrate, a first back-up layer formed over the insulating layer, a first conductive layer formed over the first back-up layer, a second back-up layer formed over the first conductive layer, a second conductive layer formed over the second back-up layer, and a third back-up layer formed over the second conductive layer.

These and other objectives are also achieved by providing a method of fabricating an interconnect structure for semiconductor devices including forming an insulator layer over a semiconductor substrate, forming a first back-up layer over the insulator layer, forming a first conductive layer over the first back-up layer, forming a second back-up layer over the first conductive layer, forming a second conductive layer over the second back-up layer and forming a third back-up layer over the second conductive layer.

It is to be understood that both the foregoing general description and the following detailed description are exemplary and explanatory and are intended to provide further explanation of the invention as claimed.

### BRIEF DESCRIPTION OF THE ATTACHED DRAWINGS

The accompanying drawings, which are included to provide a further understanding of the invention and are incorporated in and constitute a part of this application, illustrate embodiments of the invention and, together with the description, serve to explain the principle of the invention. In the drawings:

FIGS. 1A to 1B show the cross-sectional views of an interconnect in a semiconductor device according to the related art; and

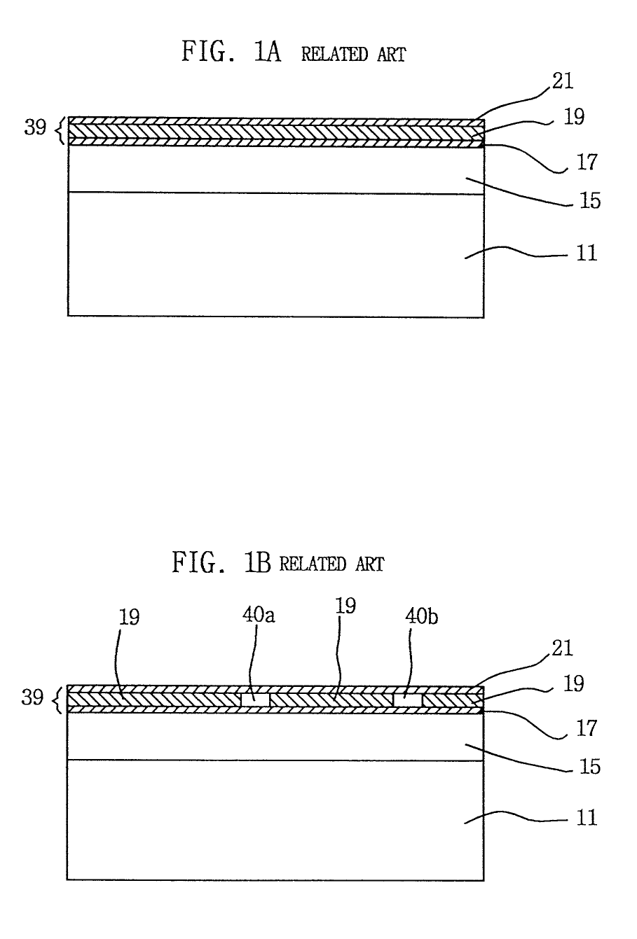

FIGS. 2A to 2B show the cross-sectional views of an interconnect in a semiconductor device according to the present invention.

### DETAILED DESCRIPTION OF PREFERRED EMBODIMENTS

Reference will now be made in detail to the preferred embodiments of the present invention, examples of which are illustrated in the accompanying drawings.

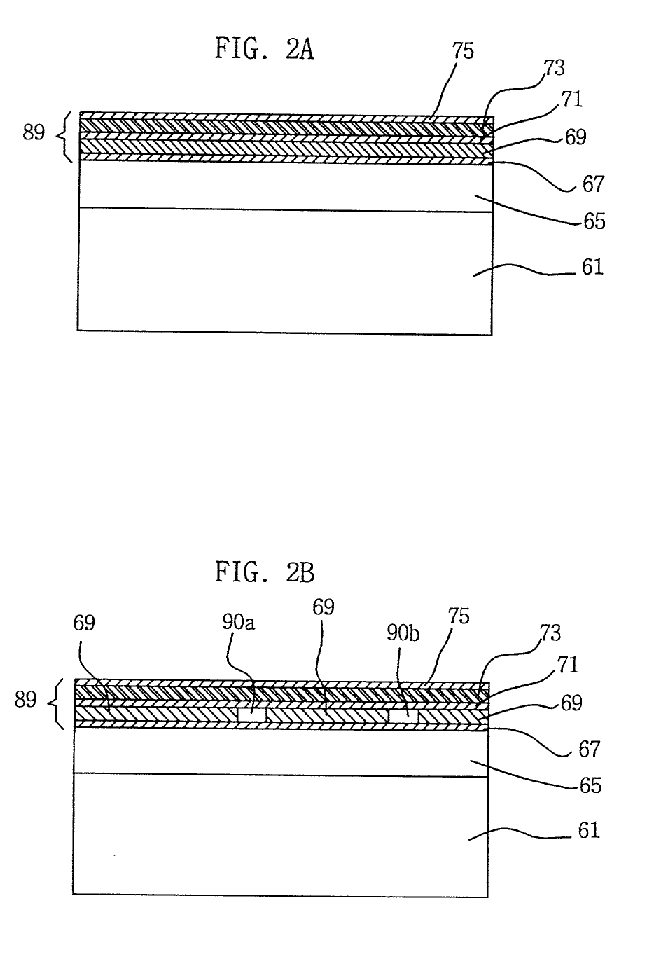

FIGS. 2A to 2B show cross-sectional views of an interconnect in a semiconductor device according to the present invention.

Referring to FIG. 2A, a thick insulating layer 65 is formed on a semiconductor substrate 61 by deposition. A first back-up layer 67, a first conductive layer 69, a second back-up layer 71, a second conductive layer 73 and a third back-up layer 75 are formed successively on the insulating layer 65 by deposition. Then, an interconnect 89 having a five-layered structure is formed by patterning the first back-up layer 67, the first conductive layer 69, the second back-up layer 71, the second conductive layer 73 and the third back-up layer 75 by a photo-etch method. A passivation layer (not shown in the drawing) is then formed on the interconnect 89.

The insulating layer 65 is formed by depositing silicon oxide through CVD. The first to third back-up layers 67, 71 and 75, having thicknesses of between about 100 and about 1500Å, are formed by depositing one of Ti, W, Mo, another transition metal or an alloy thereof by sputtering. When the first and second conductive layers 69 and 73 are formed with Al by sputtering using 0.5 to 1.5 wt % silicon, 0.5 to 1.5 wt % Cu and/or another metal alloy as the target material, sputtering conditions are altered in order to make the grain structure of the first and second conductive layers 69 and 73 different from each other. The structure of the interconnect 89 consists of five layers wherein the upper and lower layers of the second back-up layer 71 are the second and first conductive layers 73 and 69, respectively.

Referring to FIG. 2B, once electrical current of high density is applied to the interconnect 89, metal atoms of Al migrate from regions of the conductive layer 69 to other regions. Then, voids 90a and 90b are generated locally in the conductive layer by the movement of the metal atoms and the Al conductive layer 69 in the interconnect 89 becomes open due to the voids 90a and 90b.

When the second and first conductive layers 73 and 69 as the upper and lower layers of the second back-up layer 71 are deposited, a cluster or triple point which causes initial defects such as vacancies due to different particle structures between the second and first conductive layers 73 and 69 moves from sites located between the insulating layer 65 and the first conductive layer 69 of Al or between the insulating layer 65 and the second conductive layer 73 to another site. Namely, the probability of forming voids in the first and second conductive layers 69 and 73 at the same site becomes smaller. Even though voids continue their growth, the growth of voids stops at the second back-up layer 71. In this case, electrical currents pass through the second conductive layer 73 free of voids.

Accordingly, the present invention eliminates or substantially reduces EM damages by reducing the probability of forming voids at the same sites between the first conductive layer 69 placed under the second back-up layer 71 and the second conductive layer 73 placed over the second back-up layer 71 wherein the particle structures of the first and second conductive layers 69 and 73 of Al-based alloys are different from each other.

It will be apparent to those skilled in the art that various modifications and variations can be made in an interconnect structure for semiconductor devices of the present invention without departing from the spirit or scope of the invention. Thus, it is intended that the present invention cover the modifications and variations of this invention provided they come within the scope of the appended claims and equivalents.

What is claimed is:

1. An interconnect structure for semiconductor devices comprising:
a semiconductor substrate;
an insulating layer formed over the semiconductor substrate;
a first back-up layer formed over the insulating layer;
a first conductive layer formed over the first back-up layer;
a second back-up layer formed over the first conductive layer; and
a second conductive layer formed over the second back-up layer, wherein the first and second conductive layers are formed from the same composition, and wherein grain structures of said first and second conductive layers are different from each other.

2. The interconnect structure for semiconductor devices according to claim 1, further comprising:
a third back-up layer formed over the second conductive layer.

3. The interconnect structure for semiconductor devices according to claim 1, wherein the first and second conductive layers are comprised of Al-based alloys.

4. The interconnect structure for semiconductor devices according to claim 1, wherein the thickness of the first to third back-up layers each ranges from about 100 to about 1500Å.

5. The interconnect structure for semiconductor devices according to claim 1, wherein the first and second conductive layers are more conductive than the first and second back-up layers.

6. The interconnect structure for semiconductor devices according to claim 1, further comprising a passivation layer formed over the substrate.

7. An interconnect structure for semiconductor devices comprising:
an insulating layer on a semiconductor substrate;
at least two back-up layers formed over the insulating layer; and
at least two Al-based alloy layers formed over the insulating layer, wherein the at least two Al-based alloy layers are formed from the same composition, and wherein grain structures of said alloy layers are different from each other.

8. The interconnect structure for semiconductor devices according to claim 7, wherein the first back-up layer is placed between the insulating layer and the first conduction layer.

9. The interconnect structure for semiconductor devices according to claim 7, wherein the second conductive layer is placed over the second back-up layer and the first conductive layer is placed beneath the second back-up layer.

10. A method of fabricating an interconnect structure for semiconductor devices comprising:
forming an insulator layer over a semiconductor substrate;
forming a first back-up layer over the insulator layer;
forming a first conductive layer over the first back-up layer;
forming a second back-up layer over the first conductive layer; and
forming a second conductive layer over the second back-up layer, wherein the first and second conductive layers are formed from the same composition, and wherein grain structures of said first and second conductive layers are different from each other.

11. The method of fabricating an interconnected structure for semiconductor devices according to claim 10, further comprising:
forming a third back-up layer over the second conductive layer.

12. The method of fabricating an interconnect structure for semiconductor devices according to claim 10, further comprising:
patterning and etching the first and second backup and first and second conductive layers.

13. The method of fabricating an interconnect structure for semiconductor devices according to claim 10, wherein the first and second conductive layers are comprised of Al-based alloys.

14. The method of fabricating an interconnect structure for semiconductor devices according to claim 10, wherein the thickness of the first and second back-up layers each ranges from about 100 to about 1500Å.

15. The method of fabricating an interconnect structure for semiconductor devices according to claim 10, wherein the first and second conductive layers are more conductive than the first and second back-up layers.

16. The method of fabricating an interconnect structure for semiconductor devices according to claim 10, further comprising:
forming a passivation layer over the substrate.

17. The interconnect structure for semiconductor devices according to claim 1, wherein the first and second back-up layers are comprised of a transition metal or an alloy of transition metals.

18. The interconnect structure for semiconductor devices according to claim 16, wherein the transition metal comprises Ti, W or Mo.

19. The interconnect structure for semiconductor devices according to claim 7, wherein the back-up layers are comprised of transition metals or alloys of transition metals.

20. The interconnect structure for semiconductor devices according to claim 19, wherein the transition metal comprises Ti, W or Mo.

21. The method of fabricating an interconnect structure for semiconductor devices according to claim 10, wherein the first and second back-up layers are comprised of a transition metal or an alloy of transition metals.

22. The method of fabricating an interconnect structure for semiconductor devices according to claim 21, wherein the transition metal comprises Ti, W or Mo.
